(19) United States
(12) Patent Application Publication
(10) Pub. No.: US 2024/0412912 A1
(43) Pub. Date: Dec. 12, 2024

(54) TRANSFORMER INDUCTORS WITH TUNABLE COUPLING COEFFICIENT

(71) Applicant: Apple Inc., Cupertino, CA (US)

(72) Inventors: Bo YU, San Diego, CA (US); Zhang JIN, San Diego, CA (US); Zhengan YANG, Del Mar, CA (US)

(73) Assignee: Apple Inc., Cupertino, CA (US)

(21) Appl. No.: 18/207,754

(22) Filed: Jun. 9, 2023

(51) Int. Cl. H01F 17/04; H01F 27/28; H01F 27/29; H03H 11/28

(52) U.S. Cl. CPC H01F 17/04; H01F 27/2828; H01F 27/29; H03H 11/28

(57) ABSTRACT

The present disclosure describes a circuit that includes a first inductor having a first terminal and second terminal, a second inductor having a third terminal and a fourth terminal, a first capacitor circuit, and a second capacitor circuit. The first and third terminals have a same polarity. The first capacitor circuit is cross-coupled to the first terminal and the fourth terminal. The second capacitor circuit is cross-coupled to the second terminal and the third terminal. The first and second capacitor circuits adjust an electrical coupling between the first and second inductor.

### FIELD

This disclosure relates to coupled inductors and, more particularly, to inductors with a tunable coupling coefficient for high frequency signals.

### BACKGROUND

As electronic devices operate at high frequencies (e.g., for 5G applications), non-ideal frequency responses of electronic components can become more exacerbated. One example of a non-ideal frequency response can be found in two inductors coupled to one another via electric fields and magnetic fields. The coupled inductors can provide impedance transformation, power splitting, power combining, port type conversion (e.g., single-ended, differential), or the like. In the coupled-inductor design, a coupling coefficient K (e.g., total coupling) of the design can include a magnetic coupling Kₘ and an electrical coupling Kₑ. A so-called “K-curve” can be plotted for the frequency response of the coupling coefficient K. With increasing frequency, the electrical coupling Kₑ can increase the coupling coefficient K. However, at higher frequencies, a steep slope of the K-curve can impact the impedance transformation and can limit circuit bandwidth.

### SUMMARY

Embodiments of the present disclosure include a circuit having a first inductor, a second inductor, a first capacitor circuit, and a second capacitor circuit. The first inductor includes a first terminal and a second terminal. The second inductor includes a third terminal and a fourth terminal. The first and third terminals have a same polarity. The first capacitor circuit is cross-coupled to the first terminal and the fourth terminal. The second capacitor circuit is cross-coupled to the second terminal and the third terminal. The first and second capacitor circuits are configured to adjust an electrical coupling between the first and second inductors.

Embodiments of the present disclosure include a system having a first voltage source, a primary winding, a second voltage source, a secondary winding, a first capacitor circuit, and a second capacitor circuit. The first voltage source includes a first positive terminal and a first negative terminal. The primary winding is coupled to the first positive terminal and the first negative terminal. The second voltage source includes a second positive terminal and a second negative terminal. The secondary winding is coupled to the second positive terminal and the second negative terminal. The first capacitor circuit is cross-coupled to the first positive terminal and the second negative terminal. The second capacitor circuit is cross-coupled to the second positive terminal and the first negative terminal.

Embodiments of the present disclosure include a method for adjusting an electrical coupling between two inductors. The method includes generating an oscillating signal at a first wire coil. The method also includes transferring energy from the first wire coil to a second wire coil. The method further includes adjusting a coupling between the first wire coil and the second wire coil. The adjusting of the coupling includes adjusting a capacitance value of a first capacitor circuit cross-coupled to a positive terminal of the first wire coil and a negative terminal of the second wire coil. The adjusting of the coupling also includes adjusting a capacitance value of a second capacitor circuit cross-coupled to a negative terminal of the first wire coil and a positive terminal of the second wire coil.

### BRIEF DESCRIPTION OF THE DRAWINGS

Embodiments of the present disclosure are best understood from the following detailed description when read with the accompanying figures. It is noted that, according to the standard practice in the industry, various features are not drawn to scale. Features of the present disclosure can be illustrated having larger and/or smaller dimensions for clarity of discussion.

FIG. 1 shows an illustration of a system with a tunable coupling coefficient, according to some embodiments.

FIG. 2 shows an illustration of a circuit for a transformer, according to some embodiments.

FIG. 3 shows a plot graph illustrating a K-curve for inductors, according to some embodiments.

FIG. 4 shows an illustration of a circuit for a transformer with a tunable coupling coefficient, according to some embodiments.

FIG. 5 shows an illustration of layout of a transformer with a tunable coupling coefficient, according to some embodiments.

FIG. 6 shows plot graphs illustrating K-curves for inductors, according to some embodiments.

FIGS. 7 and 8 show flowcharts for methods of operating a transformer, according to some embodiments.

FIG. 9 shows an illustration of various exemplary systems or devices that can include the disclosed embodiments.

Illustrative embodiments will now be described with reference to the accompanying drawings. In the drawings, like reference numerals generally indicate identical, functionally similar, and/or structurally similar elements.

### DETAILED DESCRIPTION

The following disclosure provides different embodiments, or examples, for implementing different features of the provided subject matter. Specific examples of components and arrangements are described below to simplify the present disclosure. These are merely examples and are not intended to be limiting. The present disclosure can make use of reoccurring reference numerals and/or letters in the various examples. This repetition is for the purpose of simplicity and clarity and, unless indicated otherwise, does not in itself indicate a limiting relationship between the various embodiments and/or configurations discussed.

It is noted that references in the specification to “one embodiment,” “an embodiment,” “an example embodiment,” “exemplary,” and the like, indicate that the embodiment described may include a particular feature, structure, or characteristic, but every embodiment may not necessarily include the particular feature, structure, or characteristic. Moreover, such phrases do not necessarily refer to the same embodiment. Further, when a particular feature, structure or characteristic is described in connection with an embodiment, it would be within the knowledge of one skilled in the art to effect such feature, structure or characteristic in connection with other embodiments whether or not explicitly described.

In some embodiments, the terms “about” and “substantially” can indicate a value of a given quantity that varies within 20% of the value (e.g., ±1%, ±2%, ±3%, ±4%, ±5%, ±10%, ±20% of the value). These values are merely examples and are not intended to be limiting. The terms “about” and “substantially” can refer to a percentage of the values as interpreted by those skilled in relevant art(s) in light of the teachings herein.

In the description of at least some embodiments herein, enumerative adjectives (e.g., “first,” “second,” “third,” “primary,” “secondary,” or the like) can be used to distinguishing like elements without establishing an order, hierarchy, quantity, or permanent numeric assignment (unless otherwise noted). In some embodiments, the terms “first power source” and “second power source” can be used in a manner analogous to “i^{th} power source” and “j^{th} power source” so as to facilitate identification of two or more power sources without specifying a particular order, hierarchy, quantity, or immutable numeric correspondence.

It is to be understood that the phraseology or terminology herein is for the purpose of description and not of limitation, such that the terminology or phraseology of the present specification is to be interpreted by those skilled in relevant art(s) in light of the teachings herein.

The following disclosure describes embodiments directed to tuning a coupling coefficient of inductors in a circuit.

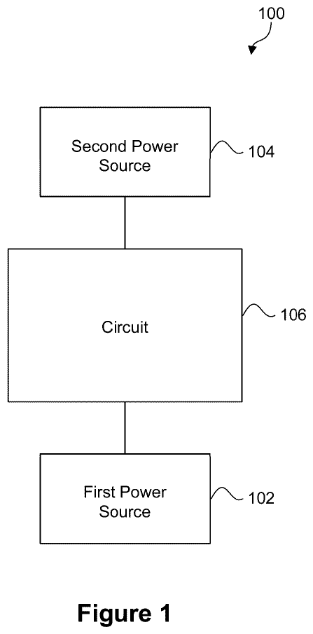

FIG. 1 shows an illustration of a system 100, according to some embodiments. System 100 can include one or more power sources and one or more circuits. In some embodiments, system 100 includes a first power source 102 (e.g., an input power source), a second power source 104 (e.g., an output power source), and a circuit 106 (e.g., a transformer circuit). First power source 102 can include batteries, power supplies, power grid sources, photovoltaic sources, a communication device, an antenna for capturing a communication signal, or the like. First power source 102 can transmit electrical signals to circuit 106. Second power source 104 can include a relay unit (e.g., another circuit) to relay power from circuit 106 to further downstream components. Power sources can be referred to as voltage sources, current sources, or the like, based on their function.

In some embodiments, circuit 106 can be used in any suitable type of electronic device, for example, a processor circuit, a memory circuit, an input/output (1/( ) circuit, a peripheral circuit, a radiofrequency (RF) circuit, a near-field communication (NFC) circuit, transformer, or the like. Circuit 106 can be used for impedance transformation, power splitting, power combining, port type conversion (e.g., single-ended, differential), or the like.

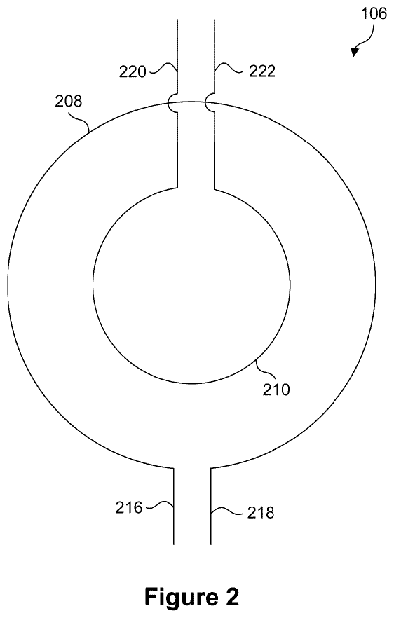

FIG. 2 shows an illustration of a circuit-level representation of circuit 106 of FIG. 1, according to some embodiments. In some embodiments, circuit 106 is a transformer that includes a first inductor 208 (e.g., a primary winding) and a second inductor 210 (e.g., a secondary winding). It is to be appreciated that first inductor 208 and second inductor 210 can be implemented according to any number of different designs. In some embodiments, first inductor 208 and second inductor 210 can be in the form of a winding of wire, a wire coil, a zig-zag pattern of wire, or the like. A winding, coil, or zig-zag pattern can include one or more repetitions (e.g., one or more turns, one or more revolutions, or the like).

In some embodiments, first inductor 208 includes a first terminal 216 and a second terminal 218. Second inductor 210 includes a third terminal 220 and a fourth terminal 222.

Alternative terms can be used to describe the terminals. In some embodiments, first terminal 216, second terminal 218, third terminal 220, and fourth terminal 222 can be referred to as a first positive terminal, a first negative terminal, a second positive terminal, and a second negative terminal, respectively. Furthermore, the polarity qualifier terms are used for simplicity of description and are non-limiting. In some embodiments, positive and negative polarities can be generalized as first and second polarities, where the first polarity is opposite the second polarity. Moreover, the terms for terminals as described above can also be used to describe terminals of other elements (e.g., first power source 102 of FIG. 1 can include a first positive terminal and a first negative terminal, second power source 104 of FIG. 1 can include a second positive terminal and a second negative terminal, or the like).

In some embodiments, first inductor 208 and second inductor 210 can inductively couple to one another (e.g., operate as a transformer for impedance transformation, power splitting, power combining, port type conversion, or the like). First inductor 208 and second inductor 210 can have a coupling coefficient K=Kₘ+Kₑ (magnetic coupling coefficient plus electrical coupling coefficient). The operation of the transformer formed by first inductor 208 and second inductor 210 can be performed at high speeds (e.g., high operating frequencies, such as in the 5G range). The transformer can have a non-constant, non-ideal frequency response (e.g., a K-curve that is not flat). It is to be appreciated that the electrical coupling Kₑ is an electrical component of the wireless inductive coupling between first inductor 208 and second inductor 210—where there is no physical connection between first inductor 208 and second inductor 210)—while the magnetic coupling Kₘ is a magnetic component of the inductive coupling.

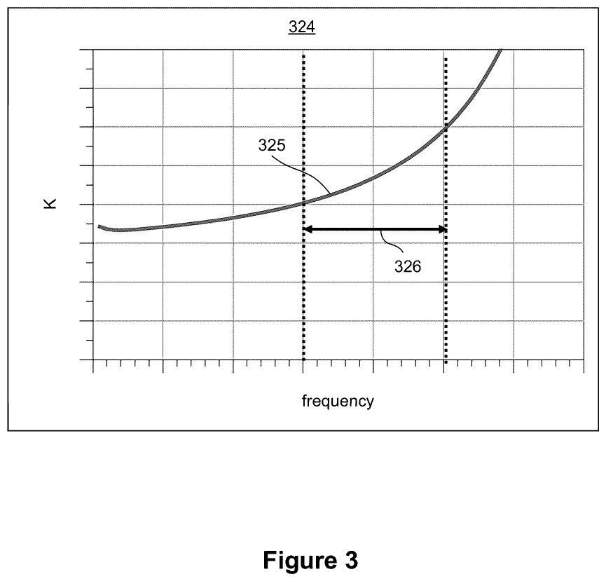

FIG. 3 shows a plot graph 324 illustrating a K-curve 325 for first inductor 208 and second inductor 210 of FIG. 2, according to some embodiments. In some embodiments, the horizontal axis of plot graph 324 represents the frequency (e.g., in Hertz). The vertical axis of plot graph 324 represents a magnitude of the coupling coefficient K. The frequency response of the coupling coefficient K includes a contribution from the electrical coupling Kₑ (which contributes a steep slope), as well as a contribution from the magnetic coupling Kₘ (which is substantially flat and level). An operating frequency range 326 can be defined by the intended application of circuit 106 (e.g., about 30 GHz to about 50 GHz can be relevant to some 5G applications). At a lower bound of operating frequency range 326, the value of the coupling coefficient K can be, for example, about 0.4. At an upper bound of operating frequency range 326, the value of the coupling coefficient K can be, for example, about 0.6. A steep slope of K-curve 325 can undesirably impact impedance transformation and limit circuit bandwidth.

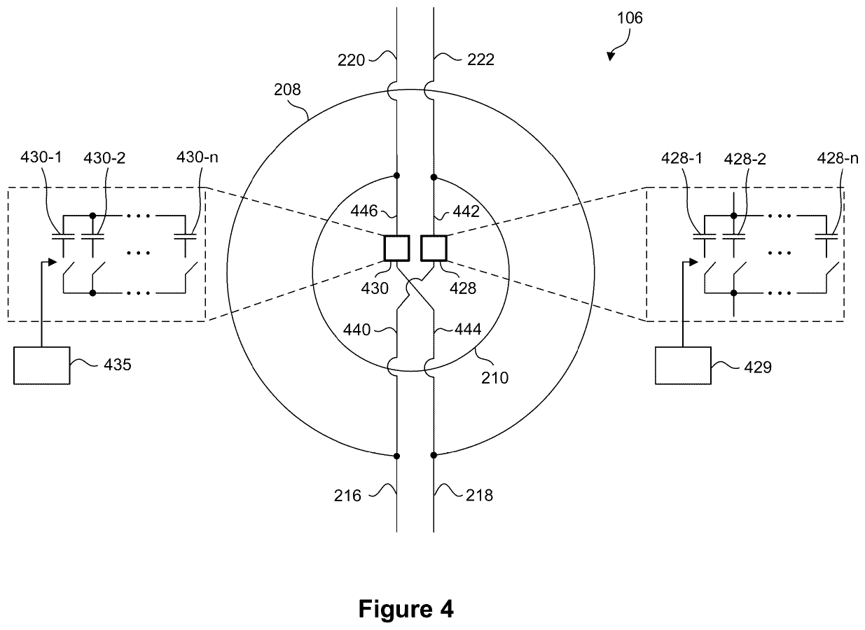

To mitigate undesirable effects of a steeply slopped K-curve 325, some embodiments of circuit 106 can implement additional circuit elements (as described below in reference to FIG. 4) to adjust or cancel the electrical coupling Kₑ and/or the magnetic coupling Kₘ. Furthermore, in some embodiments, circuit 106 can include additional circuit elements such that the electrical coupling Kₑ and/or the magnetic coupling Kₘ are adjustable (e.g., to achieve a tunable K).

FIG. 4 shows an illustration of a circuit-level representation of circuit 106 of FIG. 1, according to some embodiments. In some embodiments, circuit 106 can include one or more of the elements described in reference to FIG. 2, as well as additional elements.

In some embodiments, circuit 106 also includes a first capacitor circuit 428 and a second capacitor circuit 430. First capacitor circuit 428 is cross-coupled to first terminal 216 and fourth terminal 222. That is, a terminal 440 of first capacitor circuit 428 can be coupled to first terminal 216, and an other terminal 442 of first capacitor circuit 428 can be coupled to fourth terminal 222. Second capacitor circuit 430 is cross-coupled to second terminal 218 and third terminal 220. That is, a terminal 444 of second capacitor circuit 430 can be coupled to second terminal 218, and an other terminal 446 of second capacitor circuit 430 can be coupled to third terminal 220. The term “cross-coupling” is used in reference to the crossed connection arrangement of first capacitor circuit 428 and second capacitor circuit 430. A polarity of first terminal 216 can be the same as a polarity of third terminal 220 (e.g., positive), and a polarity of second terminal 218 can be the same as a polarity of fourth terminal 222 (e.g., negative). One arrangement that achieves the cross coupling is to have one terminal of a capacitor circuit step over another terminal of the other capacitor circuit, as shown in FIG. 4 (e.g., terminal 440 steps over terminal 444). It is be appreciated that other arrangements can be used to achieve cross-coupling. It is also to be appreciated that the cross-coupling is a physical wire connection, whereas the coupling coefficient K represents a wireless inductive coupling.

In some embodiments, first capacitor circuit 428 includes two or more selectable capacitors, for example, a selectable capacitor 428-1 up to a selectable capacitor 428-n (n≥2). The selectable capacitors of first capacitor circuit 428 can be selected independently via switch signals generated by a first control device 429. Second capacitor circuit 430 includes two or more selectable capacitors, for example, a selectable capacitor 430-1 up to a selectable capacitor 430-n (n≥2). The selectable capacitors of second capacitor circuit 430 can be selected independently via switch signals generated by a second control device 435. Capacitance values are adjusted as selectable capacitors are included or excluded from the overall circuit, thereby allowing adjustment and tuning of the coupling coefficient K. In some embodiments, first control device 429 and second control device 435 can be combined into a single control device.

In some embodiments, the capacitance values of first capacitor circuit 428 and second capacitor circuit 430 can be adjusted independently from one another. In some embodiments, for balancing, the capacitance values of first capacitor circuit 428 and second capacitor circuit 430 can be set to substantially the same value, as well as adjusted in unison. First capacitor circuit 428 can select one or more of its multiple capacitors to increase the capacitance value to decrease a rate of change of the electrical coupling Kₑ with respect to frequency. Similarly, second capacitor circuit 430 can select one or more of its multiple capacitors to increase its capacitance value to decrease a rate of change of the electrical coupling Kₑ with respect to frequency.

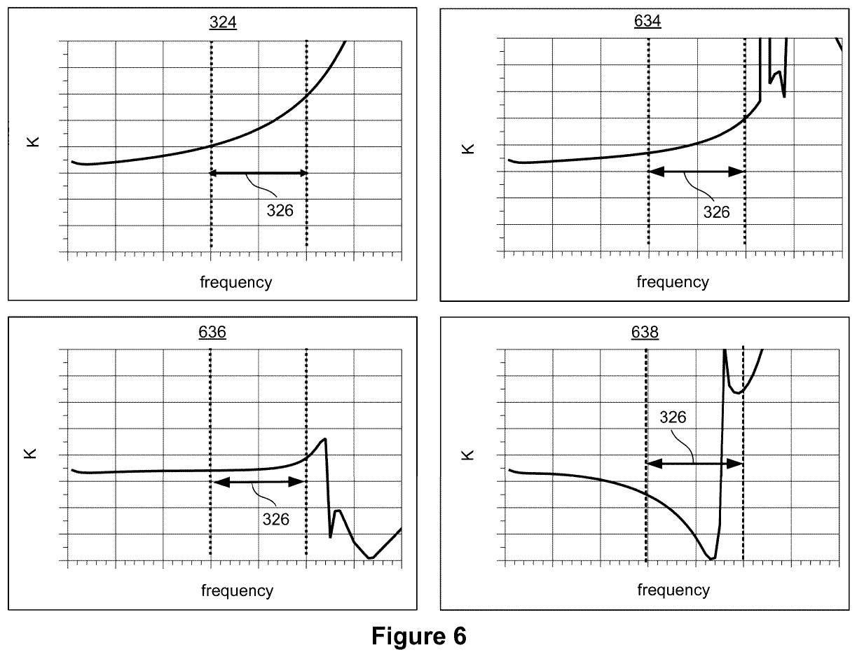

In some embodiments, the capacitance values of first capacitor circuit 428 and/or second capacitor circuit 430 can be adjusted to achieve a variety of coupling behaviors. In some embodiments, as capacitance values increase further, the impedance of circuit 106 can change to the point that the magnetic coupling Kₘ is reduced. In some embodiments, the capacitance values of first capacitor circuit 428 and/or second capacitor circuit 430 can be adjusted so as to adjust the electrical coupling Kₑ while maintaining the magnetic coupling Kₘ substantially constant. In some embodiments, the capacitance values can be set to substantially suppress the coupling coefficient K in a frequency range, thereby operating as a notch filter. In some embodiments, the capacitance values of first capacitor circuit 428 and/or second capacitor circuit 430 can be increased so as to substantially flatten a rate of change of the coupling coefficient K with respect to frequency. The K-curve behavior is illustrated and further explained in reference to FIG. 6.

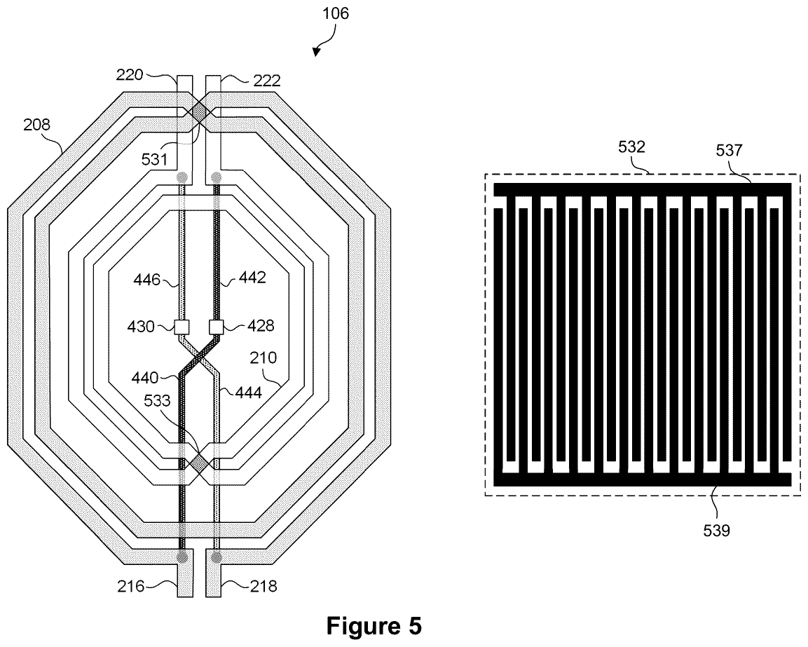

FIG. 5 shows an illustration of a layout representation of the circuit-level representation shown in FIG. 4, according to some embodiments. In some embodiments, circuit 106 can be implemented as wire traces on a substrate (e.g., semiconductor wafer/die, insulator/dielectric substrate, printed circuit board, or the like). First inductor 208 is formed by a trace of wire with two loops (can have more or fewer revolutions). Similarly, second inductor 210 is formed by a trace of wire with two loops (can have more or fewer revolutions). To insulate overlapping wire traces, the traces can be stacked on a different layer and be separated by a layer of insulating material.

In some embodiments, first inductor 208 includes an overlap region 531. Overlap region 531 includes overlapped winding traces that are separated by insulation so as to prevent bare conductor materials from touching. From the viewpoint of fabrication design, the loop traces of first inductor 208 can be deposited on a substrate, but with a break in the loop at overlap region 531. Then, an insulating step-up layer can be deposited over a “lower” one of the loops at overlap region 531. This can be followed by a deposition of a connecting trace that is disposed over the insulating step-up layer and bridge the break at overlap region 531. In this manner, additional winding traces can be implemented for additional inductance. Second inductor 210 includes an overlap region 533 with similar characteristics as described for overlap region 531. Though not explicitly labeled, it is to be appreciated that other overlap regions are present in FIG. 5 (e.g., where terminal 440 steps over terminal 444).

In some embodiments, the loop(s) of first inductor 208 and/or second inductor 210 can have an octagonal shape. The loop(s) of second inductor 210 can be disposed within the loop(s) of first inductor 208. The loops of first inductor 208 and second inductor 210 can be arranged so as to be concentric or approximately concentric. First capacitor circuit 428 and/or second capacitor circuit 430 can be disposed within the loops of first inductor 208 and second inductor 210. And, though it is not explicitly shown, it is also envisaged that some embodiments can implement first capacitor circuit 428 and/or second capacitor circuit 430 so as to be outside of the loops of first inductor 208 and second inductor 210.

In some embodiments, selectable capacitors 428-1, 428-2, 428-n, 430-1, 430-2, and/or 430-n can include a capacitor 532. Capacitor 532 can have an interdigitated structure. The interdigitated structure can be implemented as a capacitor by using a first comb-like structure 537 as a first plate of the capacitor and a second comb-like structure 539 as a second plate of the capacitor. The material of a substrate of circuit 106 can provide dielectric properties. First comb-like structure 537 and second comb-like structure 539 can be disposed such that the comb projection lines alternate periodically (e.g., a period includes a line of first comb-like structure 537 followed by a line of second comb-like structure 539.

FIG. 6 shows plot graphs 324, 634, 636, and 638, illustrating the K-curve behaviors for capacitance values of first capacitor circuit 428 and second capacitor circuit 430, according to some embodiments. For simplicity, a common capacitance value Cₙ is considered for both first capacitor circuit 428 and second capacitor circuit 430 to illustrate example behaviors of the coupling coefficient K. As discussed above, in some embodiments, first capacitor circuit 428 and second capacitor circuit 430 can have difference capacitance values. For the plot graphs in FIG. 6, the horizontal axis represents the frequency (e.g., in Hertz) and the vertical axis represents a magnitude of the coupling coefficient K.

In some embodiments, plot graph 324 is described in reference to FIG. 3 and can correspond Cₙ to C₀. As an example, the scenario in FIG. 3 corresponds to the absence of first capacitor circuit 428 and second capacitor circuit 430, which can be equivalent to the setting C₀=0 femtofarad (fF).

In some embodiments, plot graph 634 corresponds to Cₙ increased to C₁>0 (e.g., C₁=9 fF). The coupling coefficient K is flatter over frequency range 326. A rate of change of the electrical coupling Kₑ is decreased at Cₙ=C₁, in particular over frequency range 326. The control over the coupling coefficient K is allowed, not only due to the presence of first and second capacitor circuits 428 and 430 with adjustable values Cₙ, but also due to the cross-coupled arrangement of first and second capacitor circuits 428 and 430 as described in reference to FIG. 4.

In some embodiments, plot graph 636 corresponds to Cₙ having been further increased to C₂>C₁ (e.g., C₂=12 fF). At this stage, the adjustment of the capacitor circuits (e.g., first capacitor circuit 428 and second capacitor circuit 430) has substantially flattened the rate of change of the coupling coefficient K. This can also correspond to a scenario in which the electrical coupling Kₑ is adjusted (e.g., reduced to zero or near-zero) and the magnetic coupling Kₘ is maintained substantially constant. Plot graph 638 corresponds to Cₙ having been further increased to C₃>C₂ (e.g., C₃=35 fF). The coupling coefficient K can be cancelled or substantially canceled over frequency range 326. At the given frequency, a notch in the coupling coefficient K is created and the transformer is effectively rendered an open circuit.

In some embodiments, the behaviors illustrated in plot graphs 634, 636, and 638 can also depend on a given design of circuit 106 (e.g., more inductor wraps, different materials, smaller structures, or the like). In other words, other values for Cₙ are envisaged for different configurations of circuit 106. The operating frequency range 326 can cover a variety of frequency ranges (e.g., RF, 4G, 5G, about 20 to about 60 GHz, about 30 to about 50 GHz, or the like). And, by using the structures disclosed herein, adjustments of the coupling coefficient K can be achieved for a desired frequency range.

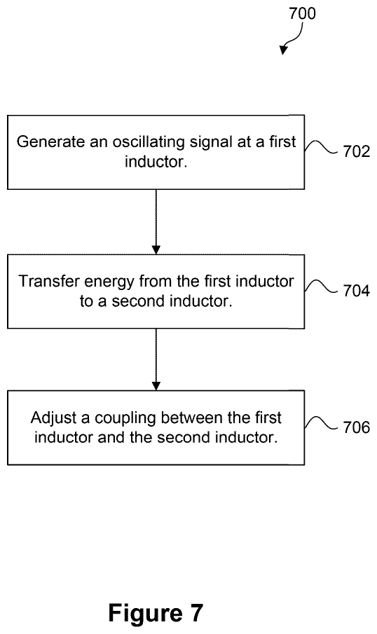

FIG. 7 shows a flowchart of a method 700 of operating a transformer, according to some embodiments. In some embodiments, method 700 can be performed using the device(s) described in reference to FIGS. 1-6. Other representations of the device(s) are within the scope of the present disclosure. Also, additional operations may be performed between various operations of method 700 and may be omitted merely for clarity and ease of description. The additional operations can be provided before, during, and/or after method 700, in which one or more of these additional operations are briefly described herein. Moreover, not all operations may be needed to perform the disclosure provided herein. Additionally, some of the operations may be performed simultaneously or in a different order than shown in FIG. 7. In some embodiments, one or more other operations may be performed in addition to or in place of the presently-described operations.

In some embodiments, at operation 702, an oscillating signal is generated at first inductor 208 of FIGS. 2, 4, and 5. The oscillating signal can be generated by first power source 102 of FIG. 1. The oscillating signal can be generated based on detection of a communication signal using an antenna.

In some embodiments, at operation 704, energy of the oscillating signal is transferred from first inductor 208 to second inductor 210 of FIGS. 2, 4, and 5. The transmission of energy can be accomplished via inductive coupling. The total coupling can be represented by the coupling coefficient K, which can include electrical coupling Kₑ and/or magnetic coupling Kₘ.

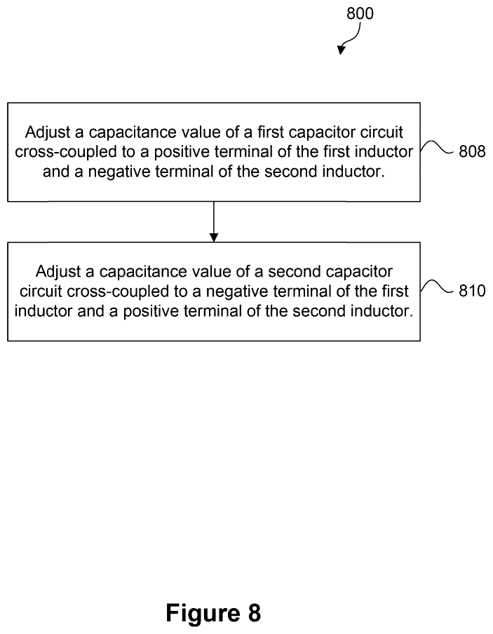

In some embodiments, at operation 706, the coupling between first inductor 208 and second inductor 210 is adjusted. As described above, transformers with the setup of circuit 106 of FIGS. 2, 4, and 5 can have a non-constant coupling coefficient K with respect to the frequency of the oscillating signal. Operation 706 allows the coupling coefficient K to be adjusted by implementing embodiments described herein, thereby mitigating undesirable phenomena arising from a non-constant coupling coefficient K (e.g., impedance mismatch). In some embodiments, operation 706 can be performed by multiple operations, such as the operations in a method 800 as shown in FIG. 8.

In some embodiments, at operation 808, a capacitance value of first capacitor circuit 428 of FIGS. 4 and 5 is adjusted. First capacitor circuit 428 is coupled to a positive terminal of the first inductor 208 and a negative terminal of the second inductor 210. The adjusting of the capacitance value of first capacitor circuit 428 can include selecting one or more of selectable capacitors 428-1 to 428-n of FIG. 4. By selecting the one or more capacitors, a capacitance of first capacitor circuit 428 is increased, thereby decreasing a rate of change of an electrical coupling between first inductor 208 and second inductor 210 over a frequency range. The increasing of the capacitance value can also be used for flattening a rate of change of the coupling between first inductor 208 and second inductor 210. Since capacitance is directly related to impedance, the adjustment of capacitance values can be used for impedance matching. The adjustment of capacitance values can also be used for power splitting, power combining, port type conversion, or the like.

In some embodiments, at operation 810, a capacitance value of second capacitor circuit 430 of FIGS. 4 and 5 is adjusted. Second capacitor circuit 430 is coupled to a negative terminal of first inductor 208 and a positive terminal of the second inductor 210. The adjusting of the capacitance value of second capacitor circuit 430 can include selecting one or more of selectable capacitors 430-1 to 430-n of FIG. 4. By selecting the one or more capacitors, a capacitance of second capacitor circuit 430 is increased. The function of adjusting the capacitance value in this manner can be useful for the purposes described above in reference to operation 806, for example, impedance matching, power splitting, power combining, port type conversion, or the like.

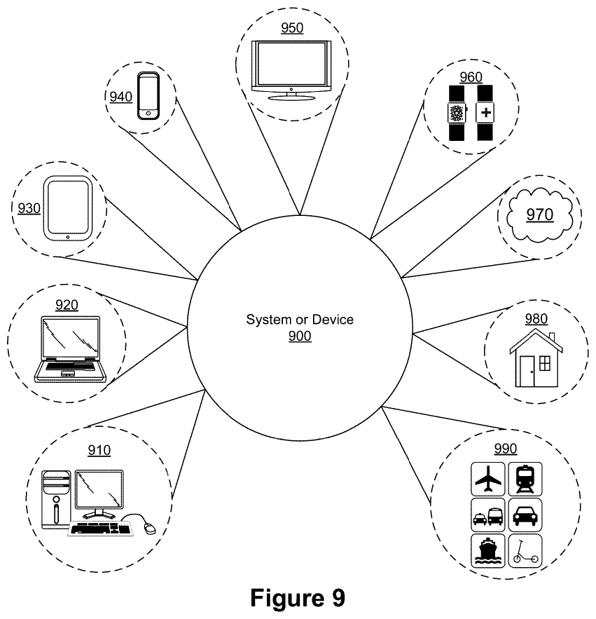

FIG. 9 shows an illustration of exemplary systems or devices that can include the disclosed embodiments. System or device 900 can incorporate one or more of the disclosed embodiments in a wide range of areas. For example, system or device 900 can be implemented in one or more of a desktop computer 910, a laptop computer 920, a tablet computer 930, a cellular or mobile phone 940, and a television 950 (or a set-top box in communication with a television).

Also, system or device 900 can be implemented in a wearable device 960, such as a smartwatch or a health-monitoring device. In some embodiments, the smartwatch can have different functions, such as access to email, cellular service, and calendar functions. Wearable device 960 can also perform health-monitoring functions, such as monitoring a user's vital signs and performing epidemiological functions (e.g., contact tracing and providing communication to an emergency medical service). Wearable device 960 can be worn on a user's neck, implantable in user's body, glasses or a helmet designed to provide computer-generated reality experiences (e.g., augmented and/or virtual reality), any other suitable wearable device, and combinations thereof.

Further, system or device 900 can be implemented in a server computer system, such as a dedicated server or on shared hardware that implements a cloud-based service 970. System or device 900 can be implemented in other electronic devices, such as a home electronic device 980 that includes a refrigerator, a thermostat, a security camera, and other suitable home electronic devices. The interconnection of such devices can be referred to as the “Internet of Things” (IoT). System or device 900 can also be implemented in various modes of transportation 990, such as part of a vehicle's control system, guidance system, and/or entertainment system.

The systems and devices illustrated in FIG. 9 are merely examples and are not intended to limit future applications of the disclosed embodiments. Other example systems and devices that can implement the disclosed embodiments include portable gaming devices, music players, data storage devices, and unmanned aerial vehicles.

It is to be appreciated that the Detailed Description section, and not the Abstract of the Disclosure section, is intended to be used to interpret the claims. The Abstract of the Disclosure section may set forth one or more but not all possible embodiments of the present disclosure as contemplated by the inventor(s), and thus, are not intended to limit the subjoined claims in any way.

Unless stated otherwise, the specific embodiments are not intended to limit the scope of claims that are drafted based on this disclosure to the disclosed forms, even where only a single example is described with respect to a particular feature. The disclosed embodiments are thus intended to be illustrative rather than restrictive, absent any statements to the contrary. The application is intended to cover such alternatives, modifications, and equivalents that would be apparent to a person skilled in the art having the benefit of this disclosure.

The foregoing disclosure outlines features of several embodiments so that those skilled in the art may better understand the aspects of the present disclosure. Those skilled in the art will appreciate that they may readily use the present disclosure as a basis for designing or modifying other processes and structures for carrying out the same purposes and/or achieving the same advantages of the embodiments introduced herein. Those skilled in the art will also realize that such equivalent constructions do not depart from the spirit and scope of the present disclosure, and that they may make various changes, substitutions, and alterations herein without departing from the spirit and scope of the present disclosure.

What is claimed is:

1. A circuit, comprising:
a first inductor having a first terminal and a second terminal;
a second inductor having a third terminal and a fourth terminal, wherein the first and third terminals have a same polarity;
a first capacitor circuit cross-coupled to the first terminal and the fourth terminal; and
a second capacitor circuit cross-coupled to the second terminal and the third terminal, wherein the first and second capacitor circuits are configured to adjust an electrical coupling between the first and second inductors.

2. The circuit of claim 1, wherein a capacitance value of the first capacitor circuit is substantially equal to that of the second capacitor circuit.

3. The circuit of claim 1, wherein the first capacitor circuit comprises a first plurality of capacitors, and wherein the second capacitor circuit comprises a second plurality of capacitors.

4. The circuit of claim 3, wherein the first and second capacitor circuits are configured to select one or more of the first and second plurality of capacitors, respectively, to operate as a notch filter.

5. The circuit of claim 3, wherein the first and second capacitor circuits are configured to select one or more of the first and second plurality of capacitors, respectively, to increase capacitance values of the first and second capacitor circuits and to decrease a rate of change of the electrical coupling over a frequency range.

6. The circuit of claim 3, wherein the first and second capacitor circuits are configured to select one or more of the first and second plurality of capacitors, respectively, to increase capacitance values of the first and second capacitor circuits to substantially flatten a rate of change of a total coupling between the first and second capacitor circuits over a frequency range, and wherein the total coupling comprises the electrical coupling and a magnetic coupling between the first and second inductors.

7. The circuit of claim 6, wherein the frequency range is between about 30 GHz and about 50 GHz.

8. The circuit of claim 3, wherein the first and second capacitor circuits are further configured to select one or more of the first and second plurality of capacitors, respectively, to adjust capacitance values of the first and second capacitor circuits and to adjust the electrical coupling while maintaining a substantially constant magnetic coupling between the first and second inductors.

9. A system, comprising:
a first voltage source having a first positive terminal and a first negative terminal;
a primary winding coupled to the first positive terminal and the first negative terminal;
a second voltage source having a second positive terminal and a second negative terminal;
a secondary winding coupled to the second positive terminal and the second negative terminal;
a first capacitor circuit cross-coupled to the first positive terminal and the second negative terminal; and
a second capacitor circuit cross-coupled to the second positive terminal and the first negative terminal.

10. The system of claim 9, wherein a capacitance value of the first capacitor circuit is substantially equal to that of the second capacitor circuit.

11. The system of claim 9, wherein the first capacitor circuit comprises a first plurality of capacitors, and wherein the second capacitor circuit comprises a second plurality of capacitors.

12. The system of claim 11, wherein the first and second capacitor circuits are configured to select one or more of the first and second plurality of capacitors, respectively, to operate as a notch filter.

13. The system of claim 11, wherein the first and second capacitor circuits are configured to select one or more of the first and second plurality of capacitors, respectively, to increase capacitance values of the first and second capacitor circuits and to decrease a rate of change of an electrical coupling between the primary and secondary windings over a frequency range.

14. The system of claim 11, wherein the first and second capacitor circuits are configured to select one or more of the first and second plurality of capacitors, respectively, to increase capacitance values of the first and second circuits to substantially flatten a rate of change of a total coupling between the first and second capacitor circuits over a frequency range, wherein the total coupling comprises an electrical coupling and a magnetic coupling between the primary and secondary windings.

15. The system of claim 14, wherein the frequency range is between about 30 GHz and 50 GHz.

16. The system of claim 11, wherein the first and second capacitor circuits are configured to select one or more of the first and second plurality of capacitors, respectively, to adjust capacitance values of the first and second capacitor circuits and to adjust an electrical coupling between the primary and secondary windings while maintaining a substantially constant magnetic coupling between the primary and secondary windings.

17. A method, comprising:
generating an oscillating signal at a first wire coil;
transferring energy from the first wire coil to a second wire coil; and
adjusting a coupling between the first wire coil and the second wire coil, wherein the adjusting comprises:
adjusting a capacitance value of a first capacitor circuit cross-coupled to a positive terminal of the first wire coil and a negative terminal of the second wire coil; and
adjusting a capacitance value of a second capacitor circuit cross-coupled to a negative terminal of the first wire coil and a positive terminal of the second wire coil.

18. The method of claim 17, wherein adjusting the capacitance values of the first and second capacitor circuits comprises selecting one or more capacitors of the first and second capacitor circuits.

19. The method of claim 18, wherein selecting the one or more capacitors comprises increasing a capacitance of the first and second capacitor circuits to decrease a rate of change of an electrical coupling between the first wire coil and the second wire coil over a frequency range.

20. The method of claim 18, wherein selecting the one or more capacitors comprises increasing a capacitance of the first and second capacitor circuits to substantially flatten a rate of change of the coupling between the first wire coil and the second wire coil over a frequency range.
